(19) United States
(12) Patent Application Publication
(10) Pub. No.: US 2026/0165178 A1
(43) Pub. Date: Jun. 11, 2026

(54) ELECTRONIC CHIP PACKAGING

(71) Applicant: STMicroelectronics International N.V., Geneva (CH)

(72) Inventors: Vincent KNOPIK, Crets en Belledonne (FR); Julien DIDION, Grenoble (FR)

(73) Assignee: STMicroelectronics International N.V., Geneva (CH)

(21) Appl. No.: 19/411,871

(22) Filed: Dec. 8, 2025

(30) Foreign Application Priority Data
Dec. 9, 2024 (EP) 24315564.5
Oct. 22, 2025 (EP) 25315371.2

(51) Int. Cl. H10W 72/20; H10W 20/41; H10W 20/43

(52) U.S. Cl. CPC H10W 72/248; H10W 20/427; H10W 20/43

(57) ABSTRACT

An electronic chip package includes terminals. At least one first terminal of the included terminals is configured to receive and/or deliver a power supply potential. At least one second terminal of the included terminals is configured to receive and/or deliver a reference potential. At least one third terminal of the included terminals is configured to receive and/or deliver a data signal. The at least one third terminal is arranged at the periphery of the package. The at least one first terminal is arranged more centrally in the package than the at least one third terminal.

### PRIORITY CLAIM

This application claims the priority benefit of European Application for Patent No. EP24315564.5, filed on Dec. 9, 2024, and claims the priority benefit of European Application for Patent No. EP25315371.2, filed on Oct. 10, 2025, the contents of which are hereby incorporated by reference in their entireties to the maximum extent allowable by law.

### TECHNICAL FIELD

The present disclosure generally concerns electronic systems and devices and, in particular, the protection and the integration of these electronic systems and devices by packages.

### BACKGROUND

Packages used to protect and connect electronic systems and devices, and for example electronic chips, need to be constantly improved to meet new requirements. A major challenge with the constant evolution of electronics is the size of the packages. There indeed exists a need for smaller and smaller electronic chip packages.

It would be desirable to be able to improve, at least partly, certain aspects of known packages for electronic devices.

There exists a need for less bulky electronic devices and, in particular, less bulky electronic device packages.

There exists a need for less bulky electronic devices processing radio frequency signals, and in particular for less bulky packages for such electronic devices.

There is a need to overcome all or part of the disadvantages of known electronic device packages.

### SUMMARY

In an embodiment, an electronic chip package comprises: at least one first terminal configured to receive and/or deliver a power supply potential; at least one second terminal configured to receive and/or deliver a reference potential; and at least one third terminal configured to receive and/or deliver a data signal, wherein said at least one third terminal is arranged at the periphery, and said at least one first terminal is arranged more centrally than said at least one third terminal.

Another embodiment provides a method of manufacturing an electronic chip package comprising: at least one first terminal configured to receive and/or deliver a power supply potential; at least one second terminal configured to receive and/or deliver a reference potential; and at least one third terminal configured to receive and/or deliver a data signal, wherein said at least one third terminal is arranged at the periphery, and said at least one first terminal is arranged more centrally than said at least one third terminal.

According to an embodiment, at least one second terminal or at least one third terminal is present between the or each first terminal and the periphery of the package.

According to an embodiment, at least one second terminal is present between a first terminal and a third terminal in at least one direction.

According to an embodiment, said package comprises at least two second terminals, the or each first terminal being arranged between two second terminals in at least one direction.

According to an embodiment, said package comprises a plurality of third terminals arranged at the periphery of the second terminal(s).

According to an embodiment, the first terminal(s) are surrounded by second terminals.

According to an embodiment, the package further comprises at least one fourth terminal configured to receive and/or deliver a control signal based on DC voltages.

According to an embodiment, the or at least one of the third terminals is configured to receive and/or deliver a radio frequency signal.

According to an embodiment, said power supply potential is different from the reference potential.

According to an embodiment, said reference potential is ground.

According to an embodiment, the second terminal(s) are coupled to a ground plane, and the first terminal(s) are coupled to a metallization level by a via extending through said ground plane.

Another embodiment provides an electronic chip comprising a package described hereabove.

According to an embodiment, the chip further comprises at least one electronic component.

Another embodiment provides a method of using a package described hereabove.

### BRIEF DESCRIPTION OF THE DRAWINGS

These features and advantages, as well as others, will be described in detail in the following description of specific embodiments, which is provided by way of example and is not intended to be limiting, in connection with the accompanying drawings, in which:

FIG. 1 schematically shows an electronic device package;

FIG. 2 shows a cross-section view of a portion of the package of FIG. 1;

FIG. 3 schematically shows examples of implementation of the package of FIG. 1; and

FIG. 4 schematically shows other examples of implementation of the package of FIG. 1.

### DETAILED DESCRIPTION

The same elements have been designated by the same references in the various figures. In particular, structural and/or functional elements common to the different embodiments may have the same references and may have identical structural, dimensional and material properties.

For the sake of clarity, only those steps and elements that are useful for understanding the described embodiments have been shown and have been described in detail.

Unless otherwise specified, when reference is made to two elements being connected to each other, this means directly connected without any intermediate elements other than conductors, and when reference is made to two elements being coupled to each other, this means that these two elements may be connected or may be connected via one or more other elements.

In the following description, where reference is made to absolute position qualifiers, such as the terms “front”, “back”, “top”, “bottom”, “left”, “right”, etc., or relative position qualifiers, such as the terms “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10% or 10°, preferably of plus or minus 5% or 5°.

Reference herein to radio frequency signals means signals having frequencies in the range from a few hertz to more than 300 GHz, for example from 3 kHz to 300 GHz.

In the radio frequency domain, electromagnetic coupling phenomena occur between two conductors transmitting signals of same frequency and which are close to each other, and this, without even being in contact. These phenomena become a source of constraint in the decrease of the size of devices using signals of the radio frequency domain.

The embodiments described hereafter concern a package intended to protect and connect an electronic system or device shown in the form of an electronic chip, and its manufacturing method. It is necessary to make such packages smaller and smaller. However, when the chip is configured to process data signals, such as for example high-frequency signals or radio frequency signals, certain constraints for the placing of connection terminals prevent the size of the package from being decreased. The solution provided herein is the following: one or more terminals configured to receive and/or deliver a power supply potential should be placed in the middle of the ground plane of the package, that is, between at least two terminals configured to receive and/or deliver a reference potential, for example, ground; while the other terminals of the chip are then placed at the periphery of the ground plane, that is, at the periphery of said at least two terminals configured to receive and/or deliver the reference potential. According to an example, the power supply potential is different from the reference potential, for example higher or lower. These other terminals are, for example, terminals configured to receive and/or deliver one or more data signals, such as high-frequency signals or radio frequency signals, and/or terminals configured to receive and/or deliver one or more control signals based on DC voltages.

An advantage of such an arrangement of the connection terminals of the package is to decrease the effective size of the package.

The embodiments described hereafter further concern a manufacturing method, a method of use of such a package, but also an electronic chip comprising such a package. Such a chip uses a package according to an embodiment to protect the component(s) or the circuit(s) that it comprises.

Further, the embodiments described hereafter are particularly configured for use in any type of industry, and in particular in the industry of circuits of interface with antennas.

Further, the embodiments described hereafter are particularly configured for use in any type of industrial market where an electronic chip protected by a package is likely to be used. More specifically, such a chip may be intended for: the automotive industry, for example in the field of automotive electrification or in the field of advanced driver assistance systems (ADAS); the industrial sector, for example in the field of green energy, in the field of infrastructure electrification, of the Internet of Things (IoT), and of smart homes, where electricity and energy consumption and data exchange are key elements; the personal electronics industry, for example in the field of mobile telephony and of the Internet of Things (IoT), as well as in the field of high-speed interfaces; and the industry of communications equipment, computers, and peripherals, for example in the field of infrastructure and data centers, and in the field of low Earth orbit (LEO) satellites.

FIG. 1 shows, very schematically, a top view of an embodiment of a package 100 of an electronic device or of an electronic chip. More specifically, FIG. 1 shows the arrangement of the various connection terminals of package 100.

Package 100 is an electronic device or chip package configured to cover the surfaces of an electronic device or chip to protect them from the external environment, while making the various connections of this electronic device or chip accessible. If the electronic device to be protected is formed from a printed circuit board, the package may cover part or all of this printed circuit board. In FIG. 1, package 100 is delimited by a rectangular shape 107. The printed circuit board on which the electronic device is formed comprises a conductive layer forming a ground plane 101, that is, a plane receiving and delivering a reference potential, for example, ground. Ground plane 101 may have various shapes depending on the needs of the electronic device or chip. In the case of FIG. 1, ground plane 101 is in the shape of a horizontal “H.”

According to an embodiment, the package comprises: at least one terminal 102 (GND), preferably two terminals for reasons of symmetry, configured to receive and/or deliver a reference potential; at least one terminal 103 (VCC) configured to receive and/or deliver a power supply potential; at least one terminal 104 (RF) configured to receive and/or deliver a radio frequency data signal; and optionally, at least one terminal 105 (CTRL) configured to receive and/or deliver a control signal based on DC voltages.

According to an embodiment, terminals 102, also called reference terminals 102, are coupled, preferably connected, to ground plane 101. According to an example, terminals 102 are, for this purpose, arranged directly above ground plane 101. Terminals 108 (GND) of ground plane 101 are shown in dotted lines, these being terminals of the ground plane which stay out of package 100.

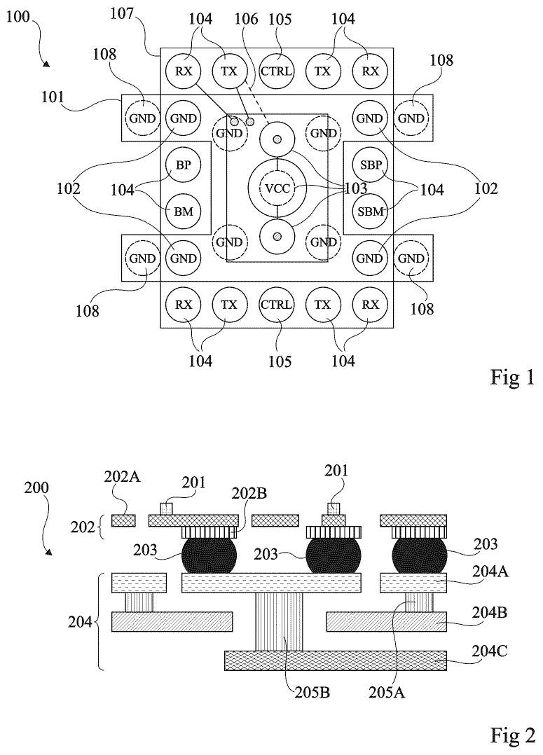

According to an embodiment, terminals 103, also called power supply terminals 103, are arranged at the level of ground plane 101 and are more particularly surrounded by ground plane 101. More particularly, in the shown example, reference terminals are distributed around terminals 103. In other words, each terminal 103 is, in at least one direction, arranged between two reference terminals 102. According to an embodiment, the power supply potential of terminals 103 is different from the reference potential, for example higher than the reference potential. According to an example, each terminal 103 is coupled to a conductive track of package 100 by a via extending through ground plane 101. This is detailed in relation with FIG. 2.

It is common to form package 100 in which the connection terminals are arranged along one or more axes of symmetry, so as to make the paths of the signals received and/or transmitted by the electronic device or chip homogeneous. According to an example, power supply terminal(s) 103 are arranged on axes of symmetry of package 100. According to an example, if package 100 comprises a plurality of axes of symmetry, power supply terminal(s) 103 are arranged at the intersection of the axes of symmetry of package 100.

According to an embodiment, terminal(s) 104 are terminals configured to receive and/or deliver data signals. According to an embodiment, these data signals are periodic signals, such as for example high frequency signals, such as radio frequency (RF) signals. Reference herein to a radio frequency signal means a signal having frequencies in the range from a few hertz to more than 300 GHz, for example in the range from 3 kHz to 300 GHz. To avoid parasitic coupling problems, it is important for these terminals 104 not to be too close to power supply terminals 103. Thus, according to an embodiment, terminals 104 are not placed directly next to power supply terminals 103 but are placed at the periphery of reference terminals 102. In other words, according to an embodiment, power supply terminal(s) 103 are arranged between reference terminals 102 so as to be made distant from terminals 104. According to an example, terminal(s) 104 are generally not arranged above ground plane 101. According to an example, terminals 104 may be terminals for transmitting and/or receiving radio frequency signals, and/or input/output (IO) terminals of the electronic device or chip.

According to an example, terminal(s) 105 are terminals configured to receive and/or deliver control signals which are not radio frequency signals. According to an embodiment, these signals are, for example, based on DC voltages. To avoid parasitic coupling problems, it is important for these terminals 105 not to be too close to power supply terminals 103. Thus, according to an embodiment, terminals 105 are not placed directly next to power supply terminals 103 but are placed at the periphery of reference terminals 102. According to an example, terminal(s) 105 are generally not arranged above ground plane 101.

According to an example, one or more terminals 104 and/or 105 may be directly coupled to a power supply terminal 103 via a dedicated interconnect 106 of package 100.

Thus, an aspect of the embodiment of package 100 is to arrange power supply terminals 103 inside ground plane 101, and not at the periphery thereof, to improve the bulk of the package and, for example, so as to make them distant from terminals 104 and 105. This enables to decrease the size of packages and, where applicable, to avoid coupling problems.

The present disclosure further concerns an electronic chip or an electronic device equipped with a package of the type of package 100 and comprising at least one electronic component. Further, it also concerns a method of manufacturing such a package and an electronic chip or an electronic device equipped with such a package.

FIG. 2 shows a cross-section view of a portion of an embodiment of a package 200 of the type of the package 100 described in relation with FIG. 1.

Package 200 is formed by a stack of layers forming metallization levels and the connection terminals of the package 200. Package 200 rests on a printed circuit board 204, itself comprising metallization levels.

More particularly, according to an example, package 200 comprises connection pads 201 forming the connection terminals. According to an example, connection pads 201 are formed of top metals in a silicon substrate. These connection pads 201 rest, for example, on a package layer level 202. This level 202 is formed, for example, by a redistribution layer 202A resting on top of and in contact with a connection ball metallization layer 202B. According to an example, pads 201 rest directly in contact on layer 202A.

According to an example, level 202 is connected, by connection balls 203, to metallization levels 204 of the package. These connection balls 203 are all in contact with portions of layer 202B and with a metal track forming part of metallization levels 204.

According to an example, printed circuit board 204 comprises three levels 204A, 204B, and 204C. According to an example, connection balls 203 are in contact with the conductive tracks of level 204A. According to an example, level 204A comprises electronic tracks coupled to level 204B via one or more electrically-conductive vias 205A. According to an example, level 204B forms a ground plane of package 200. According to an example, level 204C comprises other conductive tracks of package 200.

According to an embodiment, if connection pads 201 form power supply terminals of the type of the power supply terminals 103 described in relation with FIG. 1, pads 201 are directly coupled to level 204C by means of a via 205B extending through level 204B, directly coupling level 204A to level 204C.

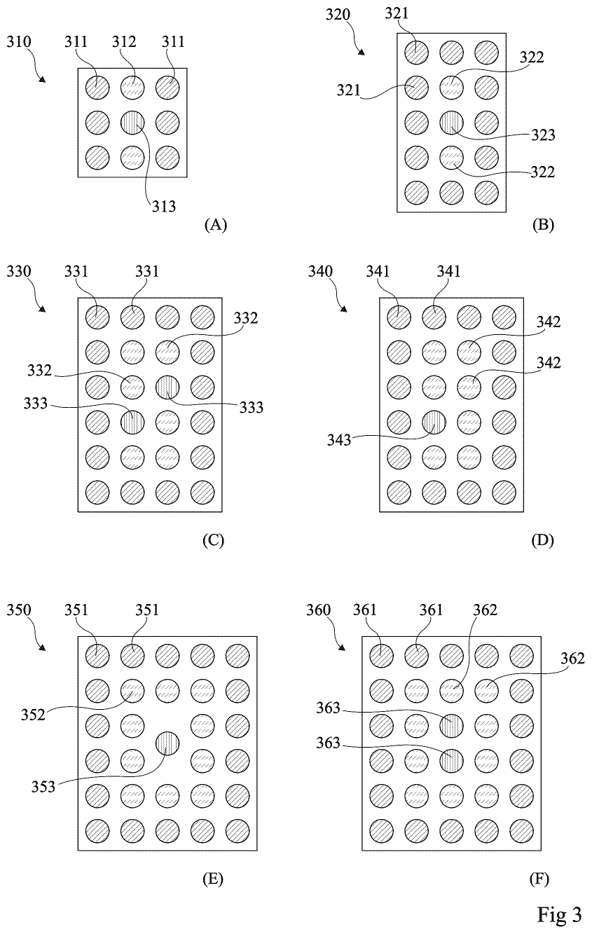

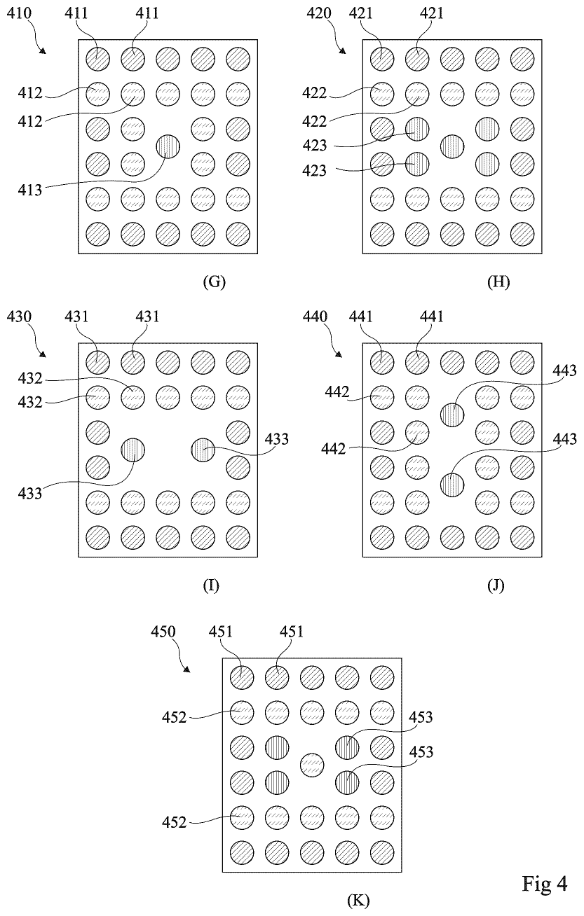

FIGS. 3 and 4 comprise views (A) to (K) illustrating examples of embodiments of a package of the type of the packages 100 and 200 described in relation with FIGS. 1 and 2.

More specifically, views (A) to (K) in FIGS. 3-4 all illustrate examples of arrangements of package connection terminals meeting the criteria described in relation with FIG. 1. Thus, each view (A) to (K) shows a package comprising communication terminals of the type of the terminals 104 or 105 described in relation with FIG. 1, reference terminals of the type of the reference terminals 102 described in relation with FIG. 1, and one or more power supply terminals of the type of the power supply terminals 103 described in relation with FIG. 1.

In each of the views (A) to (K), communication terminals are visually designated by diagonal lines, reference terminals are visually designated by dashed diagonal lines, and power supply terminals are visually designated by vertical lines.

View (A) shows a package 310 comprising communication terminals 311, reference terminals 312, and a power supply terminal 313. Package 310 has nine connection terminals arranged in the form of a square of three rows of connection terminals by three columns of connection terminals. There are six terminals 311, and these terminals are arranged in the two outer columns of the square. Terminal 313 is arranged at the center of the square, and two terminals 312 are on either side of terminal 313, vertically in the orientation of the drawing.

View (B) shows a package 320 comprising communication terminals 321, reference terminals 322, and a power supply terminal 323. Package 320 has fifteen connection terminals arranged in the form of a rectangle with five rows of connection terminals and three columns of connection terminals. There are twelve terminals 321, and these terminals are arranged all along the periphery of the rectangle. Terminal 323 is arranged at the center of the rectangle, and two terminals 322 are on either side of terminal 323, vertically in the orientation of the drawing, that is, in column 2, rows 2 and 4.

View (C) shows a package 330 comprising communication terminals 331, reference terminals 332, and two power supply terminals 333. Package 330 has twenty-four connection terminals arranged in the form of a rectangle with six rows of connection terminals and four columns of connection terminals. There are sixteen terminals 331, and these terminals are arranged all along the periphery of the rectangle. The are two terminals 333, and these terminals are arranged as close as possible to the center of the rectangle in the two central columns (in row 3, column 3 and in row 4, column 2). Six terminals 332 are arranged in the remaining positions, that is, in column 2, rows 2, 3, and 5, and in column 3, rows 2, 4, and 5.

View (D) shows a package 340 comprising communication terminals 341, reference terminals 342, and a power supply terminal 343. Package 340 has twenty-four connection terminals arranged in a rectangle with six rows of connection terminals and four columns of connection terminals. There are sixteen terminals 341, and these terminals are arranged all along the periphery of the rectangle. Terminal 343 is arranged in one of the four positions closest to the center of the rectangle in one of the two central columns (for example, in column 2, row 4). Seven terminals 342 are arranged in the remaining positions around terminal 343, that is, in column 2, rows 2, 3, and 5, and in column 3, rows 2 to 5.

View (E) shows a package 350 comprising communication terminals 351, reference terminals 352, and a power supply terminal 353. Package 350 has twenty-nine connection terminals arranged in the form of a rectangle with six rows of connection terminals and five columns of connection terminals, except for the central column, which only comprises five connection terminals. There are eighteen terminals 351, and these terminals are arranged all along the periphery of the rectangle. Terminal 353 is located at the center of the rectangle, astride the location of two connection terminals (astride rows 3 and 4). Ten terminals 352 are arranged around terminal 353.

View (F) shows a package 360 comprising communication terminals 361, reference terminals 362, and two power supply terminals 363. Package 360 has thirty connection terminals arranged in the form of a rectangle with six rows of connection terminals and five columns of connection terminals. There are eighteen terminals 361, and these terminals are arranged all along the periphery of the rectangle. There are two terminals 363, and these terminals are arranged at the center of the rectangle in a same column (column 3, rows 3 and 4). Ten terminals 362 are arranged around terminals 363.

View (G) shows a package 410 comprising communication terminals 411, reference terminals 412, and a power supply terminal 413. Package 410 has twenty-nine connection terminals arranged in the form of a rectangle with six rows of connection terminals and five columns of connection terminals, except for the central column, which only comprises five connection terminals. There are fourteen terminals 411, and these terminals are arranged in the first row and the last row of the rectangle and at the ends of the two central rows of the rectangle. Terminal 413 is arranged at the center of the rectangle, astride the location of two connection terminals (astride rows 3 and 4). Fourteen terminals 412 are arranged around terminal 413 and all along the second row and the fourth row.

View (H) shows a package 420 comprising communication terminals 421, reference terminals 422, and five power supply terminals 423. Package 420 has twenty-nine connection terminals arranged in the form of a rectangle with six rows of connection terminals and five columns of connection terminals, except for the central column, which only comprises five connection terminals. There are fourteen terminals 421, and these terminals are arranged in the first row and the last row of the rectangle, and at the ends of the two central rows of the rectangle. There are five terminals 423, and these terminals are arranged at the center of the rectangle, one terminal 423 being arranged astride the location of two connection terminals (astride rows 3 and 4). Ten terminals 422 are arranged all along the second row and the fourth row.

View (I) shows a package 430 comprising communication terminals 431, reference terminals 432, and a power supply terminal 433. Package 430 has twenty-six connection terminals arranged in the form of a rectangle with five columns of connection terminals, the first and last columns comprising six connection terminals, the second and fourth columns comprising five connection terminals, and the central column having four connection terminals. There are fourteen terminals 431, and these terminals are arranged in the first row and the last row of the rectangle and at the ends of the two central rows of the rectangle. There are two terminals 433, and these terminals are arranged on a horizontal axis of symmetry of the rectangle in the second and fourth columns, each terminal 433 being arranged astride the location of two connection terminals (astride rows 3 and 4). Ten terminals 432 are arranged all along the entire second row and the fourth row.

View (J) shows a package 440 comprising communication terminals 441, reference terminals 442, and two power supply terminals 443. Package 44 has twenty-eight connection terminals arranged in the form of a rectangle with six rows of connection terminals and five columns of connection terminals, except for the central column, which only comprises five connection terminals. There are fourteen terminals 441, and these terminals are arranged in the first row and the last row of the rectangle and at the ends of the two central rows of the rectangle. There are two terminals 443, and these terminals are arranged on a vertical axis of symmetry of the rectangle, each terminal 433 being arranged astride the location of two connection terminals (astride rows 2 and 3, respectively 4 and 5). Twelve terminals 442 are arranged on either side of terminals 443 in the second and fourth columns and at the ends of the second and fourth rows.

View (K) shows a package 450 comprising communication terminals 451, reference terminals 452, and four power supply terminals 453. Package 450 has twenty-nine connection terminals arranged in the form of a rectangle with six rows of connection terminals and five columns of connection terminals, except for the central column, which only comprises five connection terminals. There are fourteen terminals 451, and these terminals are arranged in the first row and the last row of the rectangle and at the ends of the two central rows (rows 3 and 4) of the rectangle. There are four terminals 453, and these terminals are arranged at the center (rows 2 and 3) of the second and fourth columns. Eleven terminals 452 are arranged all along the second row and the fourth row, and at the center of the rectangle astride the location of two connection terminals (column 3, astride rows 3 and 4).

Various embodiments and variants have been described. The person skilled in the art will understand that certain features of these various embodiments and variants could be combined, and other variants will become apparent to the person skilled in the art.

Finally, the practical implementation of the described embodiments and variants is within the abilities of those skilled in the art based on the functional indications given hereabove.

1. An electronic chip package, comprising:
at least one first terminal configured to receive and/or deliver a power supply potential;
at least one second terminal configured to receive and/or deliver a reference potential; and
at least one third terminal configured to receive and/or deliver a data signal;
wherein said at least one third terminal is arranged at a periphery of the package; and
wherein said at least one first terminal is arranged more centrally in the package than said at least one third terminal.

2. The package according to claim 1, wherein the at least one second terminal or the at least one third terminal is present between the at least one first terminal and the periphery of the package.

3. The package according to claim 1, wherein the at least one second terminal is present between one of the at least one first terminal and one of the at least one third terminal in at least one direction.

4. The package according to claim 1, wherein the at least one second terminal comprises two second terminals, wherein the at least one first terminal is arranged between said two second terminals in at least one direction.

5. The package according to claim 1, wherein the at least one third terminal comprises a plurality of third terminals, wherein the plurality of third terminals are arranged at a periphery of the at least one second terminal.

6. The package according to claim 1, wherein the at least one second terminal comprises a plurality of second terminals, wherein the at least one first terminal is surrounded by the plurality of second terminals.

7. The package according to claim 1, further comprising at least one fourth terminal configured to receive and/or deliver a control signal based on DC voltages.

8. The package according to claim 1, wherein each third terminal of the at least one third terminal is configured to receive and/or deliver a radio frequency signal.

9. The package according to claim 1, wherein said power supply potential is different from the reference potential.

10. The package according to claim 1, wherein said reference potential is ground.

11. The package according to claim 1, wherein each second terminal of the at least one second terminal is coupled to a ground plane, and wherein each first terminal of the at least one first terminal is coupled to a metallization level by a via extending through said ground plane.

12. An electronic chip, comprising the package according to claim 1.

13. The chip according to claim 12, further comprising at least one electronic component.

14. An electronic chip package, comprising:
a plurality of data terminals arranged at a periphery of the package;
a plurality of ground terminals arranged between a central portion of the package and the periphery of the package; and
at least one power supply terminal arranged at the central portion of the package and separated from the plurality of data terminals by one or more of the plurality of ground terminals.

15. The package of claim 14, further comprising an additional ground terminal arranged at the periphery of the package between two data terminals of the plurality of data terminals.

16. The package of claim 14, wherein the plurality of ground terminals are configured for connection to a ground plane, said ground plane including an opening where the at least one power supply terminal is arranged.
